(19) United States
(12) Patent Application Publication
(10) Pub. No.: US 2022/0234074 A1
(43) Pub. Date: Jul. 28, 2022

(54) MANUFACTURING METHOD OF COLOR FILTER

(71) Applicant: YingLight Technology Co. LTD., Dacun Township (TW)

(72) Inventor: PING-YU TSAI, Dacun Township (TW)

(21) Appl. No.: 17/578,427

(22) Filed: Jan. 18, 2022

(30) Foreign Application Priority Data
Jan. 22, 2021 (TW) 110102545

(51) Int. Cl. B05D 5/06; C09D 5/22; C09D 5/02; C09K 11/77

(52) U.S. Cl. CPC B05D 5/065; C09D 5/22; H01L 27/322; C09K 11/7708; C09K 11/7706; C09D 5/02

(57) ABSTRACT

The present invention discloses a manufacturing method of color filter. The method comprises the following steps. First, the method deposes a first color material on the substrate via a first pattern mask, forming a first color pattern, and a spray coating method is used for spraying a first color material on the substrate via the first pattern mask, therefore to form a first color pattern. Thereafter, the first pattern mask is removed and cleaned a first residual material of the first color material via laser or blow gun. The abovementioned steps will be repeated for three times to finish the color filter.

### TECHNICAL FIELD

The present invention is related to a manufacturing method of color filter. This method indicates a specific way which may remove the residual material without interfering the pattern manufacturing of the color filter per se.

### BACKGROUND OF RELATED ARTS

Quantum dot is a semiconductor nanostructure that binds internal electrons in three spatial directions. These bonds are created by electrostatic potential, the interface of two different semiconductor materials, the surface of the semiconductor, or a combination of the three thereon. Hence, quantum dots present unique optoelectronic properties. For example, when a quantum dot is excited, it emits high-purity light of various colors due to the diameter of the quantum dot. Therefore, quantum dots are often used in color patterns in color filters.

However, in the current manufacturing process of color filters, most of the excess materials (including but not limited to quantum dot materials) remain on the filter substrate are removed with a specific solvent. However, the control of the liquid solvent is extremely hard, and some materials will not be effectively removed then covering with new filter materials. Therefore, the light will be absorbed by multiple filter materials at the same time, the light extraction efficiency will be significantly reduced. The display quality of products will severely decrease. Moreover, the liquid solvent may accidentally contact with the filter material which is on the original substrate. The wasting of precious quantum dots may happen, and it further causes the problems of light leakage or light mixing in the product filter.

### SUMMARY

To resolve the drawbacks of the prior arts, the present invention discloses a manufacturing method of color filter, comprising the following steps. First, the step (A) is to depose a first pattern mask on a substrate, and the step (B) uses a spray coating method for spraying a first color material on the substrate, forming a first color pattern. The step (C) removes the first pattern mask, and cleans a first residual material of the first color material via laser or blow gun. Thereafter, the step (D) deposes a second pattern mask on the substrate, and the step (E) uses the spray coating method for spraying a second color material on the substrate, forming a second color pattern. The step (F) removes the second pattern mask, and cleans a second residual material of the second color material via laser or blow gun. Furthermore, the step (G) deposes a third pattern mask on the substrate, and step (H) uses the spray coating method for spraying a third color material on the substrate, forming a third color pattern. At last, the step (I) removes the third pattern mask, and cleans a third residual material of the third color material via laser or blow gun.

Specifically, the first color material comprises red quantum dot material. The second color material comprises green quantum dot material, and the third color material comprises blue quantum dot material or organic transparent material.

On the other hand, the present invention provides another manufacturing method of color filter, comprising the following steps. The step (a) deposes a first pattern mask on a substrate, and the step (b) uses a spray coating method for spraying a first color material on the substrate via the first pattern mask, forming a first color pattern. The step (c) deposes a first pattern protection mask on the first color pattern, and removes a first residual material of the first color pattern which is made of the first color material. The step (d) further deposes a second pattern mask on the substrate, and the step (e) uses the spray coating method for spraying a second color material on the substrate via the second pattern mask, forming a second color pattern. Thereafter, the step (f) deposes a second pattern protection mask on the first color pattern and the second color pattern, and removes a second residual material of the second color pattern which is made of the second color material. The step (g) deposes a third pattern mask on the substrate, and the step (h) uses the spray coating method for spraying a third color material on the substrate via the third pattern mask, forming a third color pattern. At last, the step (i) deposes a third pattern protection mask on the first color pattern, the second color pattern and the third color pattern, and removes a third residual material of the third color pattern which is made of the third color material.

Specifically, the first color material comprises red quantum dot material. The second color material comprises green quantum dot material, and the third color material comprises blue quantum dot material or organic transparent material.

Embodiments of the invention are illustrated by way of example, and not by way of limitation, in the figures of the accompanying drawings in which like reference numerals refer to similar elements.

### BRIEF DESCRIPTION OF THE DRAWINGS

FIG. 1 is a flow chart of the first embodiment of color filter manufacturing method of the present invention.

FIG. 2 is a schematic diagram of the first embodiment of color filter manufacturing method of the present invention.

FIG. 3 is a flow chart of the second embodiment of color filter manufacturing method of the present invention.

FIG. 4 is a schematic diagram of the second embodiment of color filter manufacturing method of the present invention.

### DETAILED DESCRIPTION OF THE INVENTION

In order to understand the technical features and practical effects of the present invention and to implement it in accordance with the contents of the specification, a preferred embodiment as shown in the figure is further described in detail as follows.

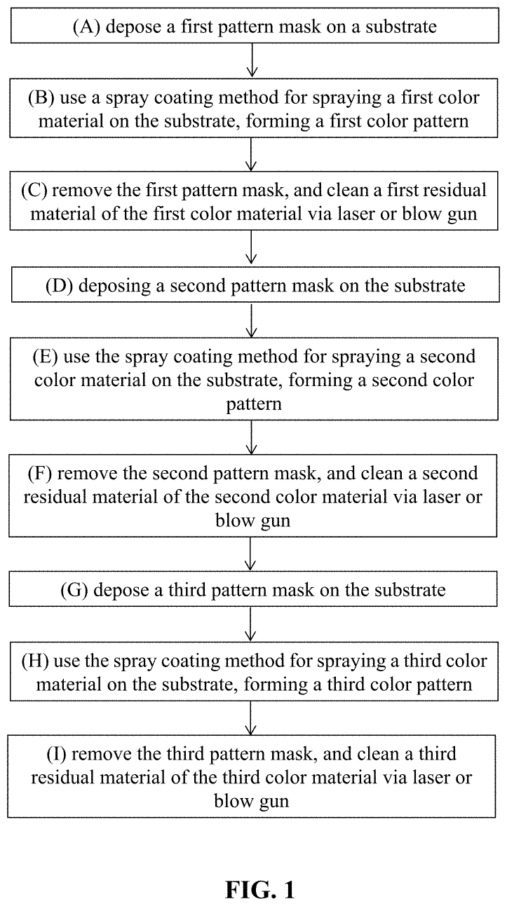

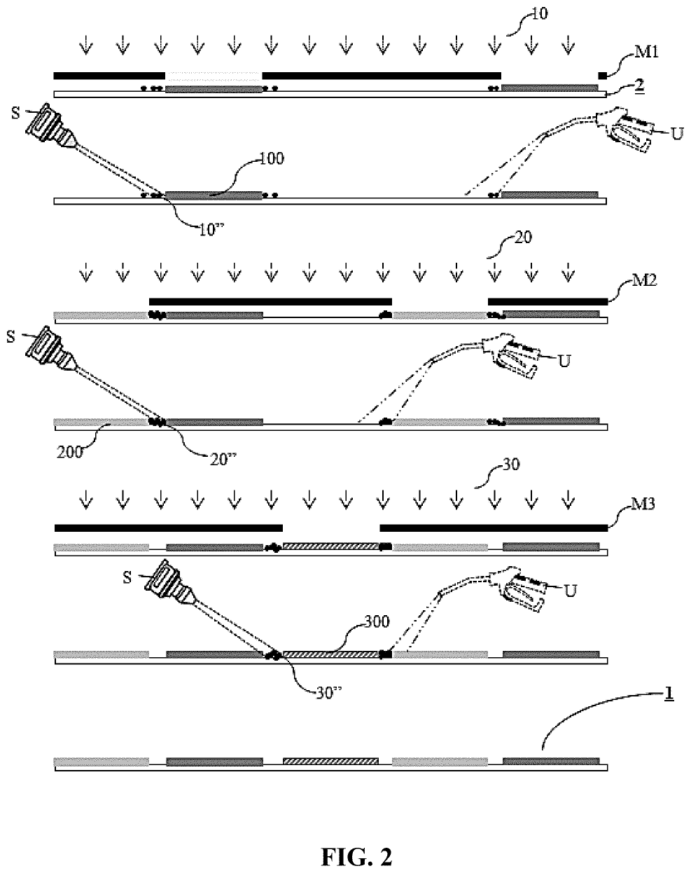

Please refer to FIG. 1 and FIG. 2. FIG. 1 is a flow chart of the first embodiment of color filter manufacturing method of the present invention. FIG. 2 is a schematic diagram of the first embodiment of color filter manufacturing method of the present invention. As shown in FIG. 1 and FIG. 2, the present embodiment of the manufacturing method of the color filter comprises the steps as follows. In step (A), a first pattern mask M1 is deposed onto the substrate 2, and the step (B) uses a spray coating method to spray a first color material 10 on the substrate 2 via the first pattern mask M1, forming a first color pattern 100. In step (C), the first pattern mask M1 is removed, and a first residual material 10″ of the first color material 10 is cleaned via laser S or blow gun U. After that, the step (D) deposes a second pattern mask M2 onto the substrate 2, and step (E) uses the spray coating method to spray a second color material 20 on the substrate 2 via the second pattern mask M2, forming a second color pattern 200. The step (F) then removing the second pattern mask M2, and cleaning second residual material 20″ of the second color material 20 via laser S or blow gun U. Hereinafter, the step (G) further deposes a third pattern mask M3 on the substrate 2, and the step (H) uses the spray coating method to spray the third color material 30 on the substrate 2 via the third pattern mask M3, forming a third color pattern 300. At last, the step (I) removes the third pattern mask M3 and cleans third residual material 30″ of the third color material 30 via laser S or blow gun U. The present invention preferably defines that the first residual material 10″, the second residual material 20″ and the third residual material 30″ mean the confirmed wastes of the first color material 10, the second color material 20 and the third color material 30 which are sprayed and coated on the substrate 2.

Please notice that a curing method is suggested to be used in the steps (B), (E) and (H) of the present embodiment. The first color material 10, second color material 20 and the third color material 30 are cured in the aforementioned steps (B), (E) and (H) respectively. Therefore, the first color pattern 100, second color pattern 200 and the third color pattern 300 are formed on the substrate 2 respectively, too. The aforementioned curing method may be performed as the thermal curing or the photo-curing. Furthermore, in the current technical field, a skilled person should understand that the thermal curing or the photo-curing result in the first color material 10, second color material 20 and the third color material 30 shall containing at least one of the photopolymer (photo-curing resin) or thermal curing resin. In fact, the photopolymer (photo-curing resin) may be any suitable material however not limited Acrylate monomers or acrylate oligomer monomers.

Specifically, when the first color material 10, second color material 20 or the third color material 30 contain the photopolymer (photo-curing resin), the curing method may be performed via high-pressure mercury lamp, electrodeless lamp, xenon lamp or the other photo-curing methods. The exposure time of the present curing method ranges from 2 to 1020 seconds, and the intensity ranges from 5 to 200 mW/cm². On the other hand, the energy exposure dose is suggested to be 10 mJ/cm² and 2,000 mJ/cm² therebetween.

Furthermore, if the first color material 10, second color material 20 or the third color material 30 contain the thermal curing resin, the curing method may be performed via oven or the other thermal curing technique. For instance, the first color material 10, second color material 20 and the third color material 30 coated on the substrate 2 are heated in an oven via the temperature ranges from 100° C. to 160° C. and the time from 1 to 300 minutes respectively, and the aforementioned first color pattern 100, second color pattern 200 and the third color pattern 300 are thus formed. Moreover, in the practical use of the present invention, this curing method may be designed to satisfy the actual requirements such as heating at 150° C. for 4 hours in an oven or just choosing to process the curing method at the room temperature until cured.

Please notice that the present color filter manufacturing method of the first embodiment is able to be used for manufacturing of the Organic Light-Emitting Diode (OLED). Hereinafter, the present manufacturing method may further comprise a configuration step (a step (J) which is not shown in FIG. 1). The configuration step is to configure a polarizing plate (not shown in FIG. 2) onto the color filter 1, therefore the light which penetrates the color filter 1 can be polarized.

In steps (A), (D) and (G), the substrate 2 may be selected from a transparent substrate. For example, the transparent substrate may be composed of any combination of glass material, metal material and/or ceramic material. Moreover, the transparent substrate may also be composed of any combination of quartz materials and/or organic polymers, the present invention does not be limited thereto. In the present embodiment, the users may refer to the needs and choose the self-defined first pattern mask M1, second pattern mask M2 or third pattern mask M3 in steps (A), (D) and (G) respectively, and the first pattern mask M1, second pattern mask M2 and the third pattern mask M3 may be suspended or attached on the aforementioned substrate 2 via the steps (A), (D) and (G) respectively, too.

In step (B), the first color material 10 comprises red quantum dot material. Specifically, the red quantum dot material includes the first chemical compound formed by elements in group II and group VI, such as but not limited to CdSe, CdTe, MgS, MgSe, MgTe, CaS, CaSe, CaTe, SrS, SrSe, SrTe, BaS, BaSe, BaTe, ZnS, ZnSe, ZnTe or CdS. On the other hand, the red quantum dot material includes the first chemical compound formed by elements in group III and group V, such as but not limited to GaN, GaP, GaAs, InN, InP or InAs. The formula/molecular structure of the aforementioned red quantum dot material is a core-shell structure or/and a nanocrystal particle doped compound which are formed via the first chemical compound and/or second chemical compound.

Moreover, the first color material 10 of the present embodiment may further comprise perovskite quantum dot material (MAX₃). The perovskite quantum dot material is mainly consisting of organic-inorganic hybrid perovskite quantum dot, all-inorganic perovskite quantum dot or the combination thereof. The perovskite quantum dot material performs unique photoelectric properties, therefore the light emitted via the perovskite quantum dot material performs high color purity. The cation M of the perovskite quantum dot material (MAX₃) comprises organic ions or the inorganic ions. The organic ion is selected form the group consisting of methylamine ion, ethylamine ion and formamidine ion, and the inorganic ion is Cs⁺. The metal ion A of the perovskite quantum dot material (MAX₃) comprises Pb²⁺, Sn²⁺ or Ge²⁺. On the other hand, the halide ion X of the perovskite quantum dot material (MAX₃) is the cubic, orthorhombic or tetragonal chloride ion (Cl—), bromide ion (Br—) or iodide ion (I—). In fact, the preferable combination of the aforementioned ions is that the first color material 10 is selected from CsPbI₃ which is an inorganic red perovskite quantum dot. The diameter of the inorganic red perovskite quantum dot ranges from 0.1-20 nm, however the range 5-10 nm is preferred.

In steps (C), (F) and (I), the laser S may be any suitable type which is not limited to Nanosecond Laser, Femtosecond Laser, Picosecond laser, CO₂ laser, Fiber laser, UV laser or green light laser. On the other hand, the YVO4-laser, YAG-laser or excimer laser may also be used. The laser S is used for cleaning first residual material 10″, second residual material 20″ and third residual material 30″ form substrate 2. However the embodiment of the present invention does not just limit the type of laser S. The wavelength of the suitable laser S may be set to short wavelength region such as the ultraviolet (100 nm to 400 nm) or the long wavelength region such as the infrared radiation (750 nm to 1 mm). In fact, the laser S may be set via the Rayleigh length (or the Rayleigh distance/area), therefore to omit the energy loss of absorption of the first residual material 10″, second residual material 20″ or the third residual material 30″ and confirm the precise cleaning of the first residual material 10″, second residual material 20″ or the third residual material 30″ which remain on substrate 2 while the first pattern mask M1, second pattern mask M2 or third pattern mask M3 are not considered in such manufacturing method.

If a blow gun U is used in steps (C), (F) and (I), the type of the blow gun U has no specific restrictions. The blow gun U may provide the Clean Dry Air (CDA), N₂ or CO₂. The blowing gas pressure can also be adjusted according to the type (model) of blow gun U or the air brush per se.

In step (E), the second color material 20 comprises green quantum dot material. Specifically, the green quantum dot material includes the first chemical compound formed by elements in group II and group VI, such as but not limited to CdSe, CdTe, MgS, MgSe, MgTe, CaS, CaSe, CaTe, SrS, SrSe, SrTe, BaS, BaSe, BaTe, ZnS, ZnSe, ZnTe or CdS. On the other hand, the green quantum dot material includes the first chemical compound formed by elements in group III and group V, such as but not limited to GaN, GaP, GaAs, InN, InP or InAs. The formula/molecular structure of the aforementioned green quantum dot material is a core-shell structure or/and a nanocrystal particle doped compound which are formed via the first chemical compound and/or second chemical compound.

The second color material 20 of the present embodiment may comprise perovskite quantum dot material (MAX₃). The perovskite quantum dot material is mainly consisting of organic-inorganic hybrid perovskite quantum dot, all-inorganic perovskite quantum dot or the combination thereof. The cation M of the perovskite quantum dot material (MAX₃) comprises organic ions or the inorganic ions. The organic ion is selected form the group consisting of methylamine ion, ethylamine ion and formamidine ion, and the inorganic ion is Cs⁺. The metal ion A of the perovskite quantum dot material (MAX₃) comprises Pb²⁺, Sn²⁺ or Ge²⁺. On the other hand, the halide ion X of the perovskite quantum dot material (MAX₃) is the cubic, orthorhombic or tetragonal chloride ion (Cl—), bromide ion (Br—) or iodide ion (I—). In fact, the preferable combination of the aforementioned ions is that the second color material 20 is selected from CsPbBr₃ which is an inorganic green perovskite quantum dot. The diameter of the inorganic green perovskite quantum dot ranges from 0.1-20 nm, however the range 2-5 nm is preferred.

In step (H), the third color material 30 comprises blue quantum dot material. Specifically, the blue quantum dot material includes the first chemical compound formed by elements in group II and group VI, such as but not limited to CdSe, CdTe, MgS, MgSe, MgTe, CaS, CaSe, CaTe, SrS, SrSe, SrTe, BaS, BaSe, BaTe, ZnS, ZnSe, ZnTe or CdS. On the other hand, the blue quantum dot material includes the first chemical compound formed by elements in group III and group V, such as but not limited to GaN, GaP, GaAs, InN, InP or InAs. The formula/molecular structure of the aforementioned blue quantum dot material is a core-shell structure or/and a nanocrystal particle doped compound which are formed via the first chemical compound and/or second chemical compound.

The third color material 30 of the present embodiment may comprise perovskite quantum dot material (MAX₃). The perovskite quantum dot material is mainly consisting of organic-inorganic hybrid perovskite quantum dot, all-inorganic perovskite quantum dot or the combination thereof. The cation M of the perovskite quantum dot material (MAX₃) comprises organic ions or the inorganic ions. The organic ion is selected form the group consisting of methylamine ion, ethylamine ion and formamidine ion, and the inorganic ion is Cs⁺. The metal ion A of the perovskite quantum dot material (MAX₃) comprises Pb²⁺, Sn²⁺ or Ge²⁺. On the other hand, the halide ion X of the perovskite quantum dot material (MAX₃) is the cubic, orthorhombic or tetragonal chloride ion (Cl—), bromide ion (Br—) or iodide ion (I—). In fact, the preferable combination of the aforementioned ions is that the second color material 20 is selected from CsPbCl₃ which is an inorganic blue perovskite quantum dot. The diameter of the inorganic blue perovskite quantum dot ranges from 0.1-20 nm, however the range 1-2 nm is preferred.

In other words, in the manufacturing method of the first embodiment, after the first pattern mask M1, second pattern mask M2 and the third pattern mask M3 are deposed onto the substrate 2, the spray coating method will be used and form the first color pattern 100, the second color pattern 200 and the third color pattern 300 thereon. This process may simplify the manufacturing method and reduce the use of color material, therefore to be advantageous for decreasing the cost and increasing the environmental protection. Comparing with the known cleaning method (the specific solvent), the first embodiment uses laser S to perform counter-cutting (precision cutting). The settings of laser S may be set via Rayleigh theory. Therefore, the precision cutting is able to directly remove the first residual material 10″, second residual material 20″ and third residual material 30″. In addition to the aforementioned advantages, the first embodiment also has the advantages of reducing the light leakage of the filter and the loss of the light source, and further improving the efficiency of light utilization.

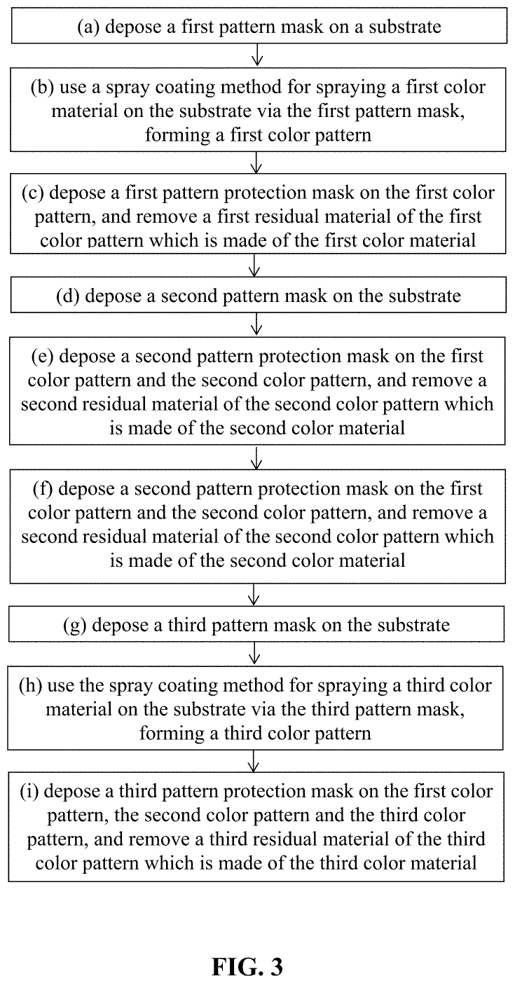

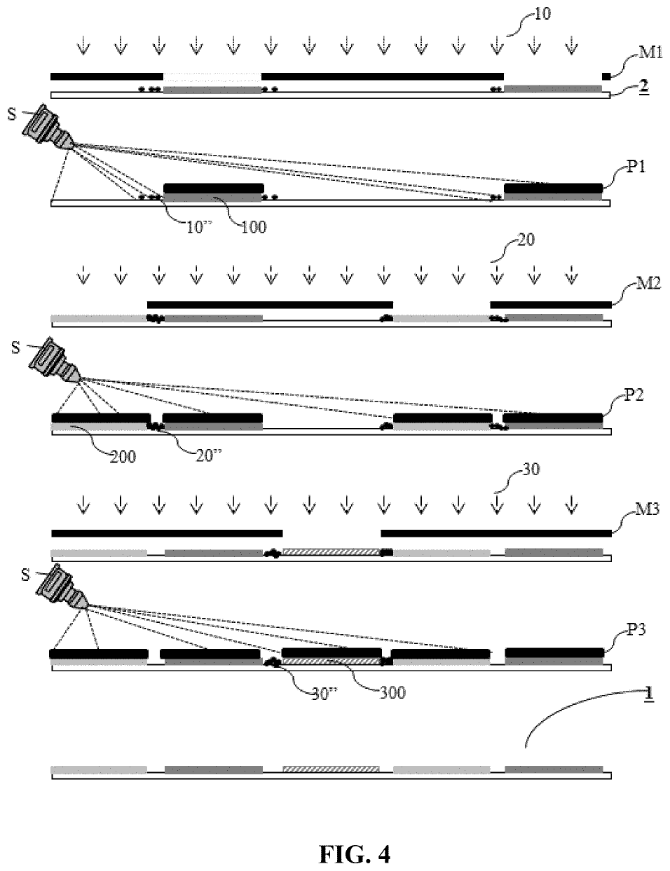

Please see FIG. 3 and FIG. 4. FIG. 3 is a flow chart of the second embodiment of color filter manufacturing method of the present invention. FIG. 4 is a schematic diagram of the second embodiment of color filter manufacturing method of the present invention. As shown in FIG. 3 and FIG. 4, the present embodiment of the manufacturing method of the color filter comprises the steps as follows. In step (a), a first pattern mask M1 is deposed onto the substrate 2, and the step (b) uses a spray coating method to spray a first color material 10 on the substrate 2 via the first pattern mask M1, forming a first color pattern 100. In step (c), the first pattern mask M1 is removed. A first pattern protection mask P1 is deposed on the first color pattern 100, and removes a first residual material 10″ of the first color pattern 100 which is made of the first color material 10 via laser S. After that, the step (d) deposes a second pattern mask M2 onto the substrate 2, and step (e) uses the spray coating method to spray a second color material 20 on the substrate 2 via the second pattern mask M2, forming a second color pattern 200. The step (f) then removes the second pattern mask M2. A second pattern protection mask P2 is deposed on the first color pattern 100 and the second color pattern 200, and removes a second residual material 20″ of the second color pattern 200 which is made of the second color material 20 via laser S. Hereinafter, the step (g) further deposes a third pattern mask M3 on the substrate 2, and the step (h) uses the spray coating method to spray the third color material 30 on the substrate 2 via the third pattern mask M3, forming a third color pattern 300. At last, the step (i) deposes a third pattern protection mask P3 onto the first color pattern 100, the second color pattern 200 and the third color pattern 300, and cleans third residual material 30″ of the third color pattern 300 which is made of the third color material 30 via laser S.

In the second embodiment, the steps (c), (f) and (i) do not directly use the laser S for cleaning the first residual material 10″, second residual material 20″ and the third residual material 30″. The first pattern protection mask P1 of step (c), the second pattern protection mask P2 of step (f) and the third pattern protection mask P3 of step (i) cover the first color pattern 100, the combination of the first color pattern 100 and the second color pattern 200, and the combination of the first color pattern 100, the second color pattern 200 and the third color pattern 300 respectively. Therefore, the first residual material 10″, second residual material 20″ and the third residual material 30″ are able to be clearly identified. The first pattern protection mask P1, second pattern protection mask P2 and the third pattern protection mask P3 are differences which are found between the first embodiment and the second embodiment of the present invention. Thus the following description will further focus on describing such difference.

Please notice that the present color filter manufacturing method of the second embodiment is able to be used for manufacturing of the Organic Light-Emitting Diode (OLED). Hereinafter, the present manufacturing method may further comprise a configuration step (a step (j) which is not shown in FIG. 3). The configuration step is to configure a polarizing plate (not shown in FIG. 4) onto the color filter 1, therefore the light which penetrates the color filter 1 can be polarized.

In current step (c), the first pattern mask M1 on the substrate 2 is needed to be removed and remain the first color material 10 which is not covered by the first pattern mask M1 (the first color pattern 100), and the first pattern protection mask P1 is relatively suspended on and covers the first color pattern 100, therefore to cover the portion of the first color pattern 100 which the user needs. For instance, if the first color pattern 100 is set to keep remaining for whole area, a large area scanning laser S will be used for removing/cleaning first residual material 10″ of the first color material 100. Otherwise, if the pattern requirements are not restricted as the first embodiment, the laser S may be any type of laser which is just required to clean all first residual material 10″ from the substrate 2. Please see FIG. 4, every first color pattern 100 are covered by first pattern protection mask P1. Therefore the laser S in FIG. 4 only cleans the first residual material 10″ which is between each of the first color patterns 100.

After that, in step (f), the second pattern mask M2 on the substrate 2 is needed to be removed and remain the first color pattern 100 and the second color material 20 which is not covered by the second pattern mask M2 (the second color pattern 200). The second pattern protection mask P2 is relatively suspended on and covers the first color pattern 100 and the second color pattern 200, therefore to cover the portion of the first color pattern 100 and the second color pattern 200 which the user needs. If the first color pattern 100 and the second color pattern 200 are required to be remained at last, the large area scanning laser S only removes the first residual material 10″ and the second residual material 20″, but the first color pattern 100 and the second color pattern 200 which are covered by second pattern protection mask P2 will be completed preserved.

At last, in step (i), the third pattern mask M3 on the substrate 2 is needed to be removed and remain the first color pattern 100, second color pattern 200 and the third material 30 which is not covered by the third pattern mask M3 (the third color pattern 300). The third pattern protection mask P3 is relatively suspended on and covers the first color pattern 100, second color pattern 200 and third color pattern 300, therefore to cover the portion of the first color pattern 100, the second color pattern 200 and third color pattern 300 which the user needs. If the first color pattern 100, second color pattern 200 and third color pattern 300 are required to be remained at last, the large area scanning laser S removes the first residual material 10″, second residual material 20″ and third residual material 30″, but the first color pattern 100, second color pattern 200 and the third color pattern 300 which are covered by third pattern protection mask P3 will be completed preserved, too.

Therefore, after the color filter manufacturing method of the second embodiment deposes the first pattern mask M1, second pattern mask M2 and third pattern mask M3 onto the substrate 2, the first color pattern 100, the second color pattern 200 and the third color pattern 300 may be respectively formed on the substrate 2 via spray coating method as the same as the first embodiment of the present invention. Therefore the second embodiment is advantageous for decreasing the cost and increasing the environmental protection, too. On the other hand, the first color pattern 100, the second color pattern 200 and the third color pattern 300 are respectively and completely protected by the first pattern protection mask P1, the second pattern protection mask P2 and the third pattern protection mask P3. The large area scanning laser S may be directly used on the substrate 2, cleaning the first residual material 10″, second residual material 20″ and the third residual material 30″ between the first color pattern 100, the second color pattern 200 and the third color pattern 300. The specific laser or high density blow gun which is used in the first embodiment can be omitted. In this way, in addition to the aforementioned advantages, the second embodiment also has the advantages of reducing the light leakage of the filter and the loss of the light source, improving the utilization efficiency of light and raising the efficiency of the manufacturing method.

As understood by a person skilled in the art, the foregoing preferred embodiments of the present invention are illustrated of the present invention rather than limiting of the present invention. It is intended to cover various modifications and similar arrangements comprised within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

What is claimed is:

1. A manufacturing method of color filter, comprising:
(A) deposing a first pattern mask on a substrate;
(B) using a spray coating method for spraying a first color material on the substrate, forming a first color pattern;
(C) removing the first pattern mask, and cleaning a first residual material of the first color material via laser or blow gun;
(D) deposing a second pattern mask on the substrate;
(E) using the spray coating method for spraying a second color material on the substrate, forming a second color pattern;
(F) removing the second pattern mask, and cleaning a second residual material of the second color material via laser or blow gun;
(G) deposing a third pattern mask on the substrate;
(H) using the spray coating method for spraying a third color material on the substrate, forming a third color pattern; and
(I) removing the third pattern mask, and cleaning a third residual material of the third color material via laser or blow gun;
wherein the first color material comprises red quantum dot material in step (B);
wherein the second color material comprises green quantum dot material in step (E); wherein the third color material comprises blue quantum dot material or organic transparent material in step (H).

2. The manufacturing method of color filter as claimed in claim 1, wherein the laser is a YVO4-laser, a YAG-laser or an excimer laser.

3. The manufacturing method of color filter as claimed in claim 1, wherein the manufacturing method of color filter further comprises a step (J) deposing a polarizing plate on to the color filter which has been manufactured after the step (I), and light which penetrates the color filter is polarized.

4. A manufacturing method of color filter, comprising:
(a) deposing a first pattern mask on a substrate;
(b) using a spray coating method for spraying a first color material on the substrate via the first pattern mask, forming a first color pattern;
(c) deposing a first pattern protection mask on the first color pattern, and removing a first residual material of the first color pattern which is made of the first color material;
(d) deposing a second pattern mask on the substrate;
(e) using the spray coating method for spraying a second color material on the substrate via the second pattern mask, forming a second color pattern;
(f) deposing a second pattern protection mask on the first color pattern and the second color pattern, and removing a second residual material of the second color pattern which is made of the second color material;
(g) deposing a third pattern mask on the substrate;
(h) using the spray coating method for spraying a third color material on the substrate via the third pattern mask, forming a third color pattern; and
(i) deposing a third pattern protection mask on the first color pattern, the second color pattern and the third color pattern, and removing a third residual material of the third color pattern which is made of the third color material;
wherein the first color material comprises red quantum dot material in step (b);
wherein the second color material comprises green quantum dot material in step (e); wherein the third color material comprises blue quantum dot material or organic transparent material in step (h).

5. The manufacturing method of color filter as claimed in claim 4, wherein the laser is a YVO4-laser, a YAG-laser or an excimer laser.

6. The manufacturing method of color filter as claimed in claim 4, wherein the manufacturing method of color filter further comprises a step (j) deposing a polarizing plate on to the color filter which has been manufactured after the step (i), and light which penetrates the color filter is polarized.
